(19) United States
(12) Patent Application Publication
(10) Pub. No.: US 2016/0208404 A1
(43) Pub. Date: Jul. 21, 2016

(54) Substrate Etch

(71) Applicant: HEWLETT-PACKARD DEVELOPMENT COMPANY, LP, Houston, TX (US)

(72) Inventors: Patrick Wayne Sadik, Corvallis, OR (US); Roger A. McKay Jr, Corvallis, OR (US)

(73) Assignee: HEWLETT-PACKARD DEVELOPMENT COMPANY, L.P., Houston, TX (US)

(21) Appl. No.: 14/914,068

(22) PCT Filed: Aug. 30, 2013
(86) PCT No.: PCT/US2013/057629

§ 371 Date: Feb. 24, 2016

(51) Int. Cl. C25F 3/12; C25F 3/14; C25F 7/00; B81C 1/00

(52) U.S. Cl. CPC C25F 3/12; B81C 1/00626; C25F 3/14; C25F 7/00; B81C 2201/0133

(57) ABSTRACT

An example provides a method including sputtering a metal catalyst onto a substrate, exposing the substrate to a solution that reacts with the metal catalyst to form a plurality of pores in the substrate, and etching the substrate to remove the plurality of pores to form a recess in the substrate.

### BACKGROUND

A number of devices may be implemented with recesses or voids (such as, e.g., a chamber or channel) in a substrate. Micro-electrical-mechanical systems (MEMS) devices, for example, may include air chambers to house components and/or to provide functionality to the devices. Printheads, which sometimes may be MEMS-based, may include firing chambers, ink feed slots, or ink channels.

### BRIEF DESCRIPTION OF THE DRAWINGS

The detailed description section references the drawings, wherein:

FIG. 1 is a flow diagram of an example method for etching a substrate;

FIGS. 2-5 illustrate sectional views of a substrate at various stages of another example method for etching the substrate;

FIGS. 6 and 7 illustrate sectional views of a substrate at various stages of another example method for etching the substrate;

FIGS. 8a and 8b illustrate sectional views of a substrate at various stages of another example method for etching the substrate;

FIGS. 9a and 9b illustrate sectional views of a substrate at various stages of another example method for etching the substrate; and

FIGS. 10a and 10b are block diagrams of an example apparatus for etching a substrate; all in which various examples may be implemented.

Certain examples are shown in the above-identified figures and described in detail below. The figures are not necessarily to scale, and various features and views of the figures may be shown exaggerated in scale or in schematic for clarity and/or conciseness.

### DETAILED DESCRIPTION OF EMBODIMENTS

Many devices are fabricated to include recesses or other openings (e.g., chambers, channels, voids, etc.). Micro-electrical-mechanical systems (MEMS) devices, for example, may include chambers to house components and/or to provide functionality to the devices. Printheads may include firing chambers, ink feed slots, or ink channels, and sometimes may be fabricated using MEMS technology. In some cases, recesses or voids may be formed in a layer and the layer may be bonded with at least one other layer to form a device.

Bulk micromachining of substrates may be performed using dry or wet etching processes. Bulk dry etch processes, however, may be lengthy as these processes are commonly performed on a one-wafer-run basis. In some wet etch operations, trenches with sloped, rather than vertical, sidewalls may be formed.

Described herein are implementations of methods for etching a substrate. In some examples, a method for etching a substrate may include contacting a substrate with a probe comprising metal and etching the substrate using a solution that reacts with the metal to form an opening in the substrate. In various implementations, the probe may be electrically biased to facilitate the etching. Etching the substrate using the probe may facilitate forming, at least in part, a device, such as, for example, a MEMS device, a printhead, or another device, or may facilitate die singulation or other substrate cutting. In various implementations, the probe may be moved relative to the substrate, or the substrate moved relative to the probe, or vice versa. In some of these implementations, an angle of the probe relative to the substrate may be modified during etching, or an angle of the substrate relative to the probe may be modified during etching. In some implementations, both the probe and the substrate may be moved relative to each other during etching. After etching, the probe may be separated from the substrate and may be used to etch another substrate or another location of the same substrate.

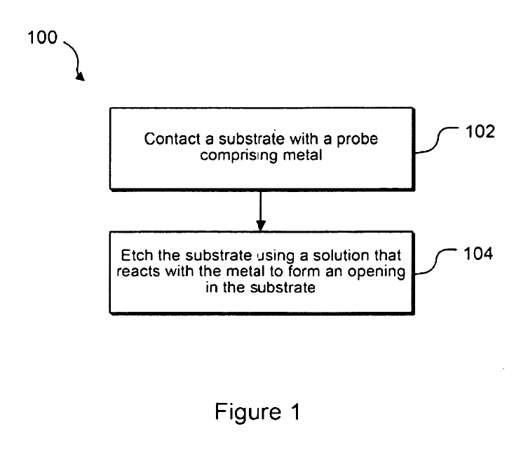

An example method 100 for etching a substrate is illustrated in FIG. 1. Processing for the method 100 may begin or proceed with contacting a substrate with a probe comprising metal, at block 102. The substrate may comprise one layer or multiple layers. For example, the substrate may comprise at least one layer of silicon, silicon germanium, a nitride, an oxide, a polymer, a ceramic, a metal, a group III-V material, a combination thereof, etc. In at least some implementations, the substrate may comprise silicon or silicon with at least one other layer thereon. In various implementations, the substrate may comprise any material suitable for forming a device, such as, for example, a MEMS device, a printhead, or another device. Various other substrate materials may be possible within the scope of the present disclosure.

It is noted that although various drawings referenced herein may depict the substrate as a single unitary layer, it should be understood that the substrate may in fact comprise multiple substrate layers and that any reference to a surface of the substrate may mean a surface of a substrate that comprises multiple layers. In some implementations, the substrate may comprise multiple substrates bonded together, and the multiple substrates may comprise the same crystal orientations or different crystal orientations.

The probe may comprise any metal that reacts with the solutions described herein to etch the substrate via metal-assisted chemical etching. For example, in various implementations, the metal may comprise a metal catalyst that reacts with a solution of hydrofluoric acid, hydrogen peroxide, or nitric acid, or a combination thereof to etch the substrate. Examples of suitable metals may include, but are not limited to, gold, silver, platinum, ruthenium, platinum, palladium, molybdenum, chromium, copper, tantalum, titanium, tungsten, and alloys thereof. In various implementations, the probe may be solid metal or may be plated or otherwise have a surface covered, at least in part, with the metal.

In various implementations, the probe may be disposed on a mount or other platform to facilitate handling of the probe. The mount may include one probe or may include a plurality of probes of the same or different shapes, depending on the pattern to be etched into the substrate. The probe, whether disposed on the mount or not, may be rigid or flexible, and may have a thickness and shape suitable for the particular etching operation. For example, the probe may comprise a wire or other raised feature that has a metal surface for contacting the substrate. Raised features may be formed, for example, by patterning a metal layer, laminating a metal pattern, etc.

The method may proceed to block 104 by etching the substrate using a solution that reacts with the metal of the probe to form an opening in the substrate. In various implementations, the solution may comprise hydrogen peroxide and/or nitric acid with hydrofluoric acid and water, and the etching operation may comprise a metal-assisted chemical etch process in which the metal is a catalyst, and the substrate surface acts as an anode and the metal acts as the cathode. The metal may catalyze the reduction of hydrogen peroxide or nitric acid, which may result in a flow of electrons from the anode to the cathode and the “sinking” of the metal probe into the substrate to anisotropically etch the substrate. In various implementations, an etch rate using the solution and the metal catalyst may be 5 μm per minute or greater. In various implementations, nitric acid added to a solution of hydrogen peroxide, hydrofluoric acid, and water may add isotrophy to the etch to dissolve the porous substrate as it is created. In some of these implementations, the amount of the nitric acid may control, at least in part, lateral etching of areas near the surface of the substrate while the ratio of the nitric acid to the hydrogen peroxide may control, at least in part, the sidewall profile.

Etching of the substrate by the solution may be performed at ambient temperature or another suitable temperature. Increasing temperature may, in some cases, increase or otherwise impact the etch rate. In some implementations, the etching of the substrate by the solution may be performed under agitation or in a still bath. The solution may be formulated by any concentration to provide a particular etch rate. Likewise, the ratio of hydrogen peroxide to hydrofluoric acid to water or nitric acid to hydrofluoric acid to water may depend on the particular etch rate, and may vary during the etch operation. In various implementations, the etching may be performed under illumination with UV or optical wavelengths, which may increase or other increase efficiency of the etch.

In various implementations, the probe may be moved relative to the substrate or the substrate moved relative to the probe, or both. For example, the angle of the probe relative to the substrate or the substrate relative to the probe, or both, may be modified during etching of the substrate. By moving the probe/substrate during etching, more complex devices may be formed or may be formed with fewer separate operations than by keeping the probe stationary.

In various implementations, the probe may be electrically biased to facilitate the etching of the substrate. Positively biasing the probe, for example, may allow the solution to be formulated devoid of hydrogen peroxide, and in at least some implementations in which the probe is positively biased, the solution may comprise hydrofluoric acid, nitric acid, and water, and is substantially devoid of hydrogen peroxide.

In various implementations, the probe may be separated from the substrate after the etching. The probe may be re-used to etch another substrate or another location of the same substrate.

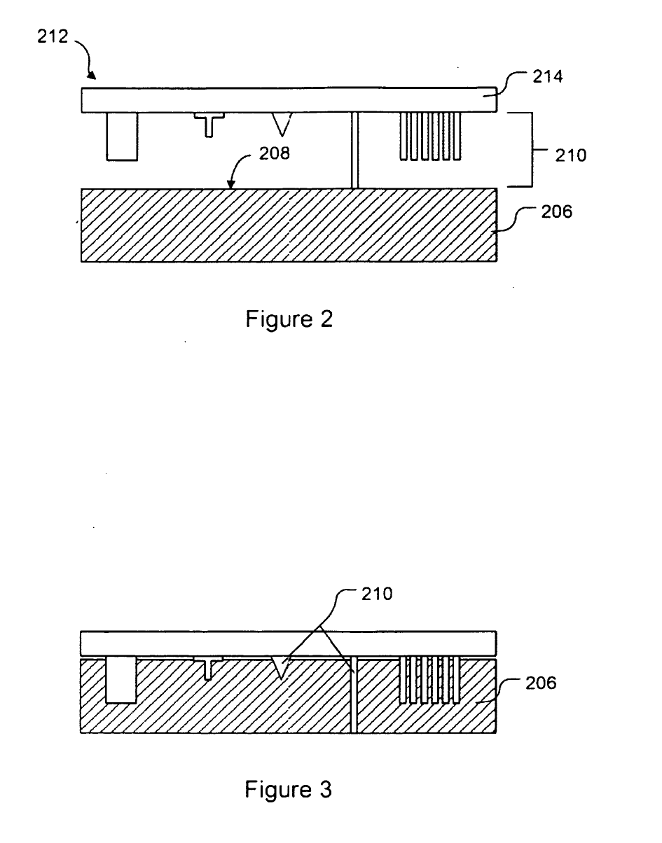

Understanding of the various methods for etching a substrate as described herein may be facilitated with reference to FIGS. 2-9a/9b, which describe various operations for etching a substrate by way of sectional views of the substrate at various stages of various example methods. It should be noted that various operations discussed and/or illustrated may be generally referred to as multiple discrete operations in turn to help in understanding various implementations. The order of description should not be construed to imply that these operations are order dependent, unless explicitly stated. Moreover, some implementations may include more or fewer operations than may be described.

Turning now to FIG. 2, a method for etching a substrate 206 may begin or proceed with contacting a surface 208 of the substrate 206 with a probe 210 of a template 212. The probe 210 may comprise metal, as discussed herein. As shown, the template 212 includes a plurality of probes 210, with various shapes and sizes. In various implementations, the template 212 may include a mount 214 on which the probes 210 may be disposed. In other implementations, the probes 210 may be free-standing or individually controlled. In various implementations, the probes 210 may comprise a wire or a raised feature on the mount 214, or a combination thereof.

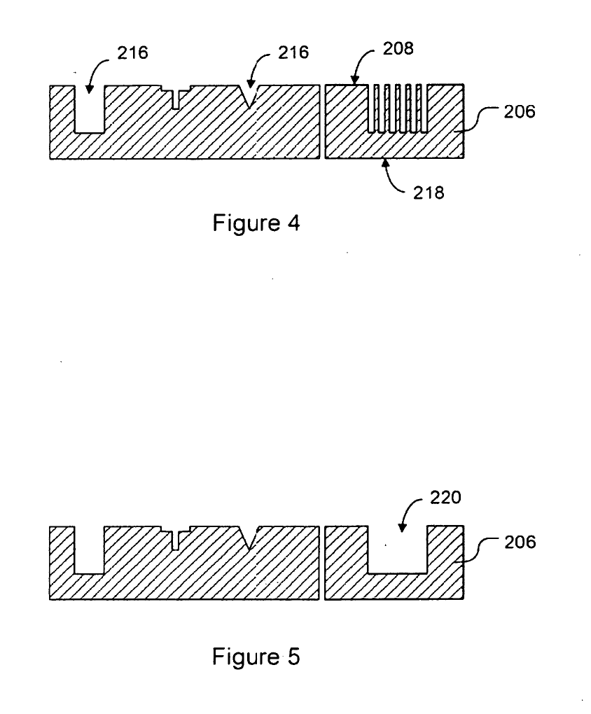

The method may proceed with etching the substrate 206 using a solution that reacts with the metal of the probes 210, as shown in FIG. 3, to form openings 216 in the substrate 206 corresponding to the locations of the probes 210, as shown in FIG. 4. The probe 210 may be separated from the substrate 206 after the etching, and re-used to etch another substrate or another location of the same substrate 206.

The openings 214 may comprise trenches, blind holes, or through-holes. To form through-holes, the etching may continue until a probe 210 reaches a second surface 218, opposite the first surface 208, of the substrate 206 so that the opening 216 extends through an entire thickness of the substrate 206. The substrate 206 including the openings 216 may form, at least in part, a MEMS device, a printhead, or another device. In various ones of these implementations, a printhead may be formed with the MEMS device.

In some implementations, after etching the substrate 206 to form the openings 216, the substrate 206 may be etched to remove at least some of the openings 216 to form at least one recess 220 in the substrate 206, as shown in FIG. 5. In various implementations, all or fewer than all of the plurality of openings 216 may be etched. As shown, for example, some of the openings 216 may not be etched while other openings 216 are etched to form the recess 220. The substrate 206 may be etched to remove the openings 216 using a wet etch with an etchant such as, but not limited to, tetra-methyl ammonium hydroxide or potassium hydroxide. In other implementations, the substrate 206 may be etched to remove the openings 216 using a dry etch. In various implementations, the recess or recesses 220 may further form, at least in part, a MEMS device, a printhead, or another device.

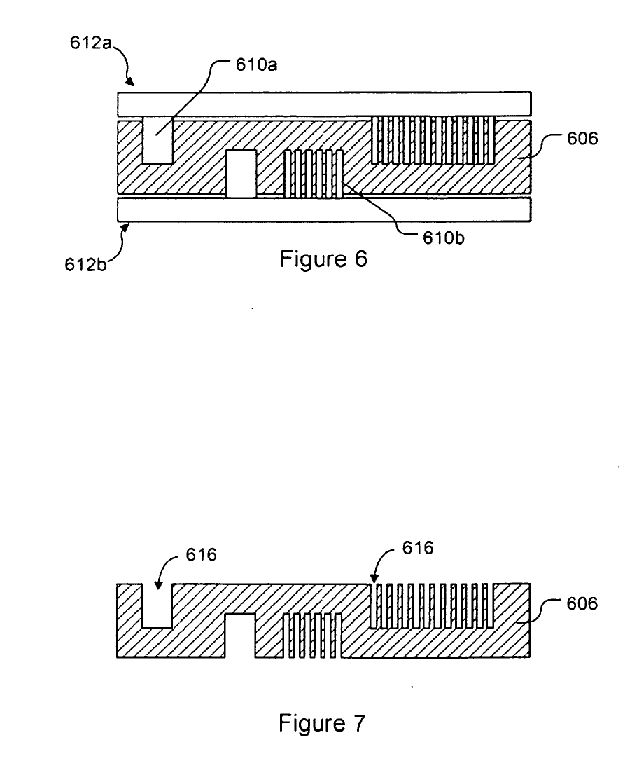

In various implementations, a substrate may be etched on opposite surfaces for forming a device. As shown in FIG. 6, a method for etching a substrate may include contacting opposite surfaces of a substrate 606 with probes 610a, 610b of templates 612a, 612b, and etching the substrate 606 using a solution that reacts with the metal of the probes 610a, 610b to form openings 616 in the substrate 606 corresponding to the locations of the probes 610a, 610b, as shown in FIG. 7. The substrate 606 including the openings 616 may form, at least in part, a MEMS device, a printhead, or another device. In various ones of these implementations, a printhead may be formed with the MEMS device.

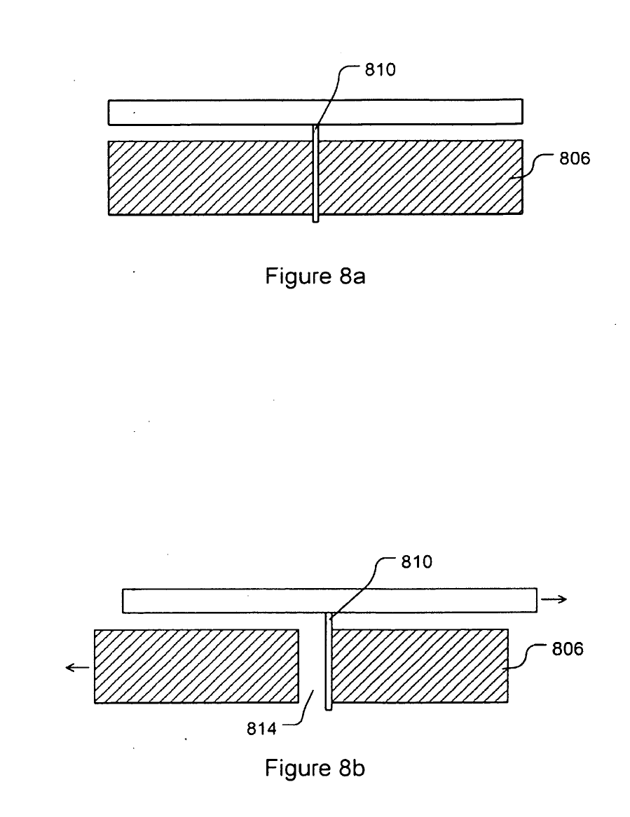

In various implementations, moving a probe and/or a substrate relative to each other may facilitate forming more complex patterns in a substrate. FIGS. 8a and 8b show an example of etching a substrate 806 in which a probe 810 is moved laterally relative to the substrate 806 during etching. As shown in FIG. 8a, the method may begin or proceed with etching the substrate 806 using a solution that reacts with the metal of the probe 810, as shown in FIG. 8a. The probe 810 may be moved laterally relative to the substrate 806, as shown in FIG. 8b, which may form an opening 814 in the substrate 806. In various implementations, moving the probe 810 during the etch may allow an opening 814 larger than the probe 810 to be formed in the substrate 806. For example, in various implementations, moving the probe 810 may be used to form a line or to cut the substrate 806 (such as, e.g., to singulate die, etc.). Although not shown here, in various implementations, the probe 810 may be moved in multiple directions during the etch to form other patterns in the substrate 806. For example, the probe 810 may be moved laterally (such as, e.g., movement along an x-axis or a y-axis, or a combination thereof, where the x-axis and y-axis are parallel with the surface of the substrate 806) or up/down (such as, e.g., movement along a z-axis), or both, during an etch. In other implementations, the substrate 806 may be moved laterally relative to the probe 810 instead of or in addition to moving the probe 810 laterally relative to the substrate 806 during etching.

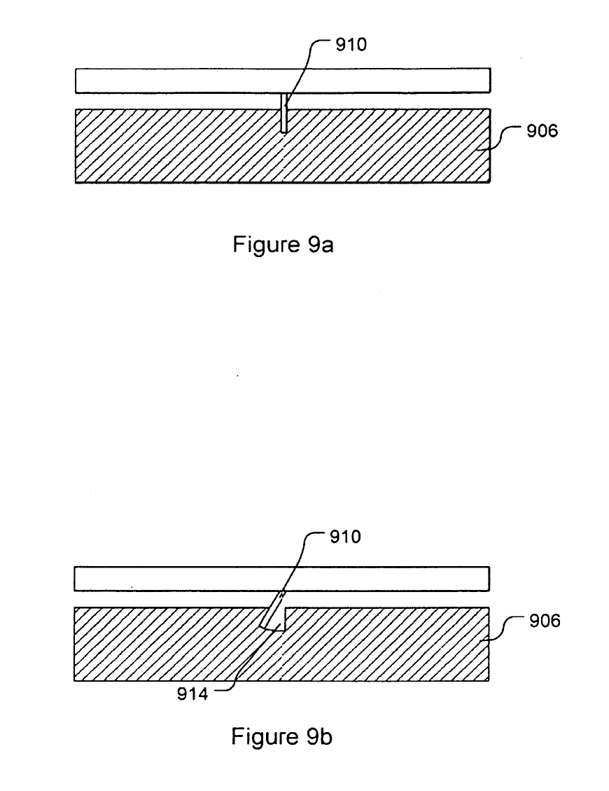

FIGS. 9a and 9b show an example of etching a substrate 906 in which an angle of a probe 910 is modified during etching of the substrate 906. The method may begin or proceed with etching the substrate 906 using a solution that reacts with the metal of the probe 910, as shown in FIG. 9a. The probe 910 may be angled during the etch, as shown in FIG. 9b, which may form an opening 914 in the substrate 906. In other implementations, the angle of the substrate 906 relative to the probe 910 may be modified during etch instead of or in addition to modifying the angle of the probe 910 relative to the substrate 906.

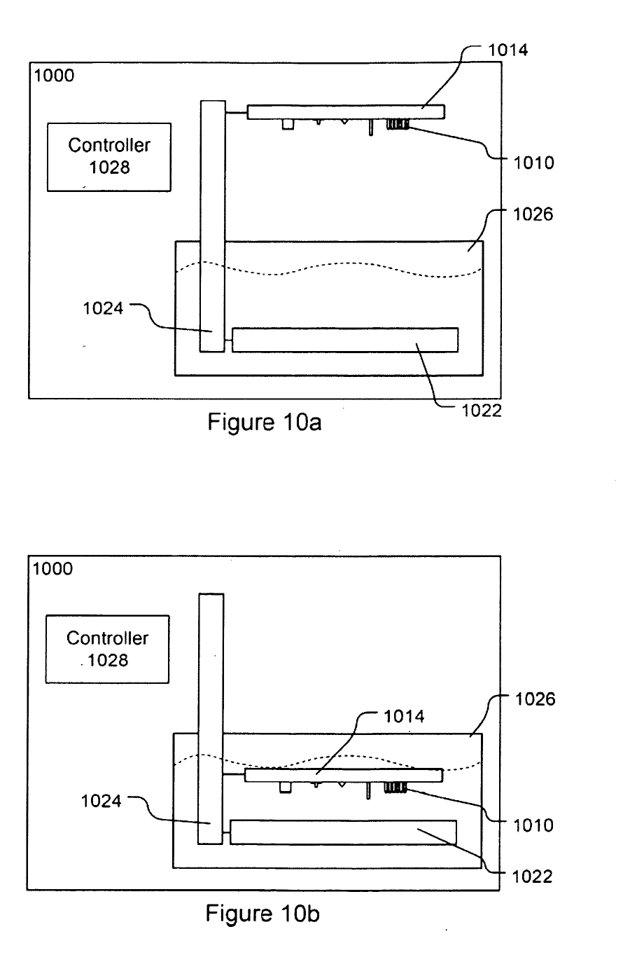

FIGS. 10a and 10b are block diagrams of an example apparatus 1000 for etching a substrate. The apparatus 1000 may include probes 1010 comprising metal and a platform 1022 configured to hold a substrate. In various implementations, the probes 1010 may be disposed on a mount 1014. In various implementations, the mount 1014 may be configured to electrically bias the probes 1010 when the probes 1010 are in contact with a substrate on the platform 1022.

The apparatus 1000 may include an actuator assembly 1024 configured to bring the probes 1010 and the platform 1022 into proximity to cause the probes 1010 to contact a substrate disposed on the platform 1022. In various implementations, the actuator assembly 1024 may be configured to move the probes 1010 or modify an angle of the probes 1010, or both, relative to a substrate on the platform 1022 when the probes are in contact with the substrate. In some implementations, the platform 1022 may be configured to move the substrate or modify an angle of the substrate, or both, relative to the probes 1010 instead of or in addition to moving the actuator assembly 1024 during etching. In some of these implementations, the platform 1022 may be configured to bring the substrate toward the probes 1010 instead of in addition to the actuator assembly 1024 bringing the probes 1010 into proximity with the platform 1022.

A fluid unit 1026 may provide a solution to a substrate when the probes 1010 are in contact with the substrate, the solution to react with the metal to form an opening in the substrate. The fluid unit 1026 may comprise a bath tank, a sprayer module, or other application module for providing the solution to a substrate mounted on the platform 1022.

The apparatus 1000 may include a controller 1028 to control at least one aspect of the apparatus 1000. In various implementations, the controller 1028 may cause the actuator assembly 1024 to bring the probes 1010 and the platform 1022 into proximity to cause the probes 1010 to contact a substrate (such as, e.g., moving the probes 1010 toward the platform 1022 or the platform 1022 toward the probes 1010, or both), to move the probes 1010 relative to the substrate when the probes 1010 are in contact with the substrate, or to modify an angle of the probes 1010 relative to the substrate when the probes 1010 are in contact with the substrate, or some combination thereof. In various implementations, the controller 1028 may electrically bias the probes 1010 when the probes 1010 are in contact with a substrate on the platform 1022. In various implementations, the controller 1028 may control the fluid unit 1026 to cause the solution to be provided to the substrate.

Various aspects of the illustrative embodiments are described herein using terms commonly employed by those skilled in the art to convey the substance of their work to others skilled in the art. It will be apparent to those skilled in the art that alternate embodiments may be practiced with only some of the described aspects. For purposes of explanation, specific numbers, materials, and configurations are set forth in order to provide a thorough understanding of the illustrative embodiments. It will be apparent to one skilled in the art that alternate embodiments may be practiced without the specific details. In other instances, well-known features are omitted or simplified in order not to obscure the illustrative embodiments.

Flow diagrams are provided to describe various methods for etching a substrate, in accordance with various implementations. While the flow diagrams illustrate various operations in a particular order, the drawings are not intended to limit the present disclosure to any particular order. Additionally, the drawings are not intended to imply that all operations are required for all implementations.

The phrases “in an example,” “in various examples,” “in some examples,” “in various embodiments,” and “in some embodiments” are used repeatedly. The phrases generally do not refer to the same embodiments; however, they may. The terms “comprising,” “having,” and “including’ are synonymous, unless the context dictates otherwise. The phrase “A and/or B” means (A), (B), or (A and B). The phrase “A/B” means (A), (B), or (A and B), similar to the phrase “A and/or B”. The phrase “at least one of A, B, and C” means (A), (B), (C), (A and B), (A and C), (B and C), or (A, B and C). The phrase “(A) B” means (B) or (A and B), that is, A is optional. Usage of terms like “top”, “bottom”, and “side” are to assist in understanding, and they are not to be construed to be limiting on the disclosure.

Although certain embodiments have been illustrated and described herein, it will be appreciated by those of ordinary skill in the art that a wide variety of alternate and/or equivalent embodiments or implementations calculated to achieve the same purposes may be substituted for the embodiments shown and described without departing from the scope of this disclosure. Those with skill in the art will readily appreciate that embodiments may be implemented in a wide variety of ways. This application is intended to cover any adaptations or variations of the embodiments discussed herein. It is manifestly intended, therefore, that embodiments be limited only by the claims and the equivalents thereof.

What is claimed is:

1. A method comprising:
contacting a substrate with a probe comprising metal; and
etching the substrate using a solution that reacts with the metal to form an opening in the substrate.

2. The method of claim 1, further comprising modifying an angle of the probe relative to the substrate during said etching.

3. The method of claim 1, further comprising moving the probe relative to the substrate or the substrate relative to the probe, or both, during said etching.

4. The method of claim 1, further comprising separating the probe from the substrate after said etching.

5. The method of claim 1, wherein the solution comprises hydrogen peroxide, hydrofluoric acid, and water.

6. The method of claim 1, further comprising electrically biasing the probe during said etching, and wherein the solution comprises hydrofluoric acid, nitric acid, and water, and is substantially devoid of hydrogen peroxide.

7. The method of claim 1, wherein the opening comprises a trench, a blind hole, or a through-hole.

8. The method of claim 1, wherein said contacting comprises contacting a first surface of the substrate with the probe, and wherein the method further comprises continuing to etch the substrate using the solution until the probe reaches a second surface, opposite the first surface, of the substrate.

9. The method of claim 1, wherein the metal is selected from a group consisting of gold, silver, platinum, ruthenium, platinum, palladium, molybdenum, chromium, copper, tantalum, titanium, tungsten, and alloys thereof.

10. A method comprising:
contacting a substrate with a probe comprising metal; and
forming, at least in part, a micro-electrical-mechanical-systems (MEMS) device by etching the substrate using a solution catalyzed by the metal.

11. The method of claim 10, wherein the MEMS device comprises at least a portion of a printhead.

12. An apparatus comprising:
a mount including a probe comprising metal;
a platform to hold a substrate;
an actuator assembly to bring the mount and the platform into proximity to cause the probe to contact the substrate; and
a fluid unit to provide a solution to the substrate when the probe is in contact with the substrate, the solution to react with the metal to form an opening in the substrate.

13. The apparatus of claim 12, wherein the probe comprises a wire or a raised feature on the mount.

14. The apparatus of claim 12, wherein the actuator assembly is to move the probe or modify an angle of the probe, or both, relative to the substrate when the probe is in contact with the substrate.

15. The apparatus of claim 12, wherein the mount is to electrically bias the probe when the probe is in contact with the substrate.
